(19) United States
(12) Patent Application Publication
(10) Pub. No.: US 2022/0284344 A1
(43) Pub. Date: Sep. 8, 2022

(54) METHOD FOR TRAINING MACHINE LEARNING MODEL FOR IMPROVING PATTERNING PROCESS

(71) Applicant: ASML NETHERLANDS B.V., Valdhoven (NL)

(72) Inventors: Ziyang MA, Mountain View, CA (US); Jin CHENG, Santa Clara, CA (US); Ya LUO, Saratoga, CA (US); Leiwu ZHENG, San Jose, CA (US); Xin GUO, Sunnyvale, CA (US); Jen-Shiang WANG, Sunnyvale, CA (US)

(73) Assignee: ASML NETHERLANDS B.V., Valdhoven (NL)

(21) Appl. No.: 17/631,557

(22) PCT Filed: Jul. 30, 2020
(86) PCT No.: PCT/EP2020/071453

§ 371 Date: Jan. 31, 2022

Related U.S. Application Data
(60) Provisional application No. 62/886,058, filed on Aug. 13, 2019.

(51) Int. Cl. G06N 20/00

(52) U.S. Cl. CPC G06N 20/00

(57) ABSTRACT

A method for training a machine learning model configured to predict values of a physical characteristic associated with a substrate and for use in adjusting a patterning process. The method involves obtaining a reference image; determining a first set of model parameter values of the machine learning model such that a first cost function is reduced from an initial value of the cost function obtained using an initial set of model parameter values, where the first cost function is a difference between the reference image and an image generated via the machine learning model; and training, using the first set of model parameter values, the machine learning model such that a combination of the first cost function and a second cost function is iteratively reduced, the second cost function representing a difference between measured values and predicted values.

### CROSS-REFERENCE TO RELATED APPLICATIONS

This application claims priority of U.S. application 62/886,058 which was filed on Aug. 13, 2019 and which is incorporated herein in its entirety by reference.

### FIELD

The present disclosure relates to techniques of improving the performance of a device manufacturing process. The techniques may be used in connection with a lithographic apparatus.

### BACKGROUND

A lithography apparatus is a machine that applies a desired pattern onto a target portion of a substrate. Lithography apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g. a silicon wafer) that has a layer of radiation-sensitive material (resist). In general, a single substrate will contain a network of adjacent target portions that are successively exposed. Known lithography apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, there is provided a method of training a machine learning model configured to predict values of a physical characteristic associated with a substrate for use in adjusting a patterning process. The method involves obtaining a reference image associated with a desired pattern to be printed on the substrate; determining a first set of model parameter values of the machine learning model such that a first cost function is reduced from an initial value of the cost function obtained using an initial set of model parameter values, wherein the first cost function is a difference between the reference image and an image generated via the machine learning model; and training, using the first set of model parameter values, the machine learning model such that a combination of the first cost function and a second cost function is iteratively reduced. In an embodiment, the second cost function is a difference between measured values and predicted values of the physical characteristic associated with the desired pattern, the predicted values being predicted via the machine learning model.

Furthermore, in an embodiment, there is provided a computer program product comprising a non-transitory computer readable medium having instructions recorded thereon, the instructions when executed by a computer system implementing the aforementioned methods.

### BRIEF DESCRIPTION OF THE DRAWINGS

Embodiments will now be described, by way of example only, with reference to the accompanying drawings in which:

FIG. 1 shows a block diagram of various subsystems of a lithography system, according to an embodiment;

FIG. 2 depicts an example flow chart for modeling and/or simulating at least part of a patterning process, according to an embodiment;

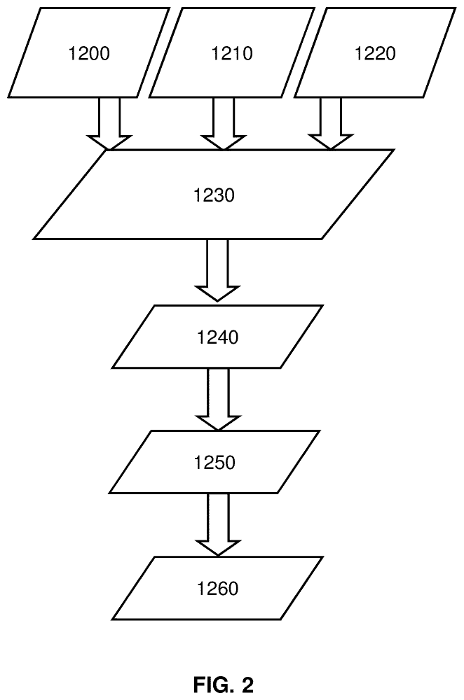

FIG. 3 is a flow chart for a method of training a machine learning model configured to predict values of a physical characteristic associated with a substrate for use in adjusting a patterning process, according to an embodiment;

FIG. 4 illustrates an example of a machine learning model having multiple layers used for training according to the method in FIG. 3, according to an embodiment;

FIG. 5A and FIG. 5B illustrate example pattern shift with respect to a grid causing grid-dependency error, according to an embodiment;

FIG. 6 schematically depicts an embodiment of a scanning electron microscope (SEM), according to an embodiment;

FIG. 7 schematically depicts an embodiment of an electron beam inspection apparatus, according to an embodiment;

FIG. 8 is a block diagram of an example computer system, according to an embodiment;

FIG. 9 is a schematic diagram of a lithographic projection apparatus, according to an embodiment;

FIG. 10 is a schematic diagram of an extreme ultraviolet (EUV) lithographic projection apparatus, according to an embodiment;

FIG. 11 is a more detailed view of the apparatus in FIG. 10, according to an embodiment; and

FIG. 12 is a more detailed view of the source collector module of the apparatus of FIG. 10 and FIG. 11, according to an embodiment.

### DETAILED DESCRIPTION

Before describing embodiments in detail, it is instructive to present an example environment in which embodiments may be implemented.

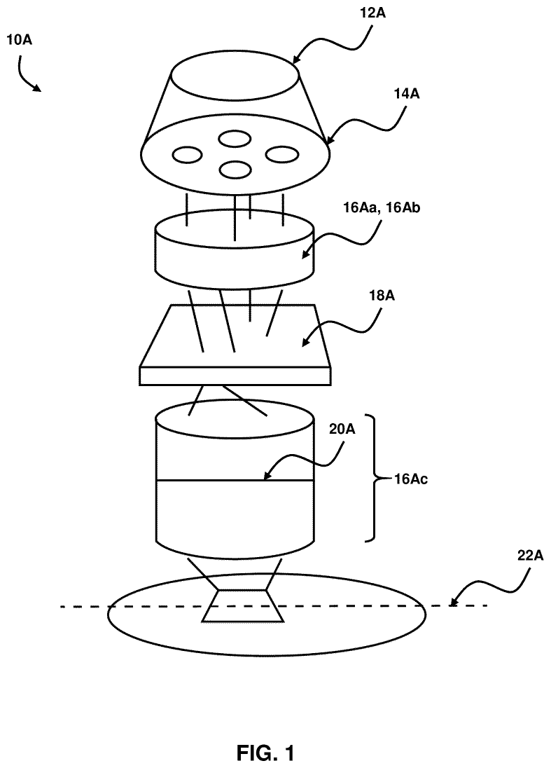

FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(θmax), wherein n is the refractive index of the media between the substrate and the last element of the projection optics, and θmax is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it may be desirable to separate the optical properties of the patterning device from the optical properties of the rest of the lithographic projection apparatus including at least the source and the projection optics.

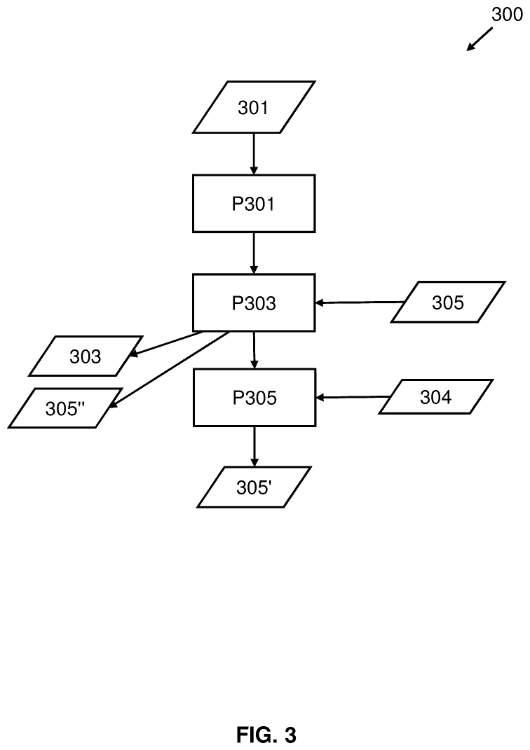

In an embodiment, assist features (sub resolution assist features and/or printable resolution assist features) may be placed into the design layout based on how the design layout optimized according to the methods of the present disclosure. For example, in an embodiment, the methods employ a machine learning based model to determine a patterning device pattern. The machine learning model may be a neural network such as a convolution neural network that can be trained in a certain way (e.g., as discussed in FIG. 3) to obtain accurate predictions at a fast rate, thus enabling a full-chip simulation of the patterning process.

A neural network may be trained (i.e., whose parameters are determined) using a set of training data. The training data may comprise or consist of a set of training samples. Each sample may be a pair comprising or consisting of an input object (typically a vector, which may be called a feature vector) and a desired output value (also called the supervisory signal). A training algorithm analyzes the training data and adjusts the behavior of the neural network by adjusting the parameters (e.g., weights of one or more layers) of the neural network based on the training data. The neural network after training can be used for mapping new samples.

In the context of determining a patterning device pattern, the feature vector may include one or more characteristics (e.g., shape, arrangement, size, etc.) of the design layout comprised or formed by the patterning device, one or more characteristics (e.g., one or more physical properties such as a dimension, a refractive index, material composition, etc.) of the patterning device, and one or more characteristics (e.g., the wavelength) of the illumination used in the lithographic process. The supervisory signal may include one or more characteristics of the patterning device pattern (e.g., CD, contour, etc. of the patterning device pattern).

Given a set of N training samples of the form {(x₁, y₁, (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object. The vector space associated with these vectors is often called the feature space. It is sometimes convenient to represent g using a scoring function f: X×Y→ [symbol] such that g is defined as returning the y value that gives the highest score:

$$g ( x ) = arg {max}_{y} f ( x , y ) .$$

Let F denote the space of scoring functions.

The neural network may be probabilistic where g takes the form of a conditional probability model g(x)=P(y|x), or f takes the form of a joint probability model f(x, y)=P(x, y).

There are two basic approaches to choosing f or g: empirical risk minimization and structural risk minimization. Empirical risk minimization seeks the neural network that best fits the training data. Structural risk minimization includes a penalty function that controls the bias/variance tradeoff. For example, in an embodiment, the penalty function may be based on a cost function, which may be a squared error, number of defects, EPE, etc. The functions (or weights within the function) may be modified so that the variance is reduced or minimized.

In both cases, it is assumed that the training set comprises or consists of one or more samples of independent and identically distributed pairs (xᵢ, yᵢ). In an embodiment, in order to measure how well a function fits the training data, a loss function L: Y×Y→ [symbol] ^{≥0} is defined. For training sample (xᵢ, yᵢ), the loss of predicting the value ŷ is L(yᵢ, ŷ).

The risk R(g) of function g is defined as the expected loss of g. This can be estimated from the training data as

$${R}_{emp} ( g ) = \frac{1}{N} {\sum }_{i} L ( {y}_{i} , g ( {x}_{i} ) ) .$$

In an embodiment, machine learning models of the patterning process can be trained to predict, for example, contours, patterns, CDs for a mask pattern, and/or contours, CDs, edge placement (e.g., edge placement error), etc. in the resist and/or etched image on a wafer. An objective of the training is to enable accurate prediction of, for example, contours, aerial image intensity slope, and/or CD, etc. of the printed pattern on a wafer. The intended design (e.g., a wafer target layout to be printed on a wafer) is generally defined as a pre-OPC design layout which can be provided in a standardized digital file format such as GDSII or OASIS or other file format.

An exemplary flow chart for modelling and/or simulating parts of a patterning process is illustrated in FIG. 22. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (a) settings as well as any particular illumination shape (e.g. off-axis radiation shape such as annular, quadrupole, dipole, etc.), where 6 (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

In patterning processes, like photolithography, electron beam lithography, directed self-assembly, etc., an energy sensitive material (e.g., photoresist) deposited on the substrate typically undergoes a pattern transfer step (e.g., via light exposure). Following the pattern transfer step, various post steps such as resist baking, and subtractive processes such as resist development, etches, etc., are applied. These post-exposure steps or processes exert various effects on the substrate that cause the patterned layer or etches to have structures having dimensions different from targeted dimensions.

Computational analysis of the patterning processes employ a prediction model that, when properly calibrated, can produce accurate prediction of dimensions output from the patterning processes. A model of post-exposure processes is typically calibrated based on empirical measurements. The calibration process includes running a test wafer with different process parameters, measuring resulting critical dimensions after post-exposure processes, and calibrating the model to the measured results. In practice, well calibrated models, making fast and accurate predictions of dimensions, serve to improve device performance or yield, enhance process windows or increase design choices. In an example, use of deep convolutional neural networks (CNNs) for modeling post-exposure processes yields model accuracy comparable or superior to that produced with traditional techniques, which often involve modeling with physical term expressions or closed form equations. Compared to the traditional modelling techniques, deep learning convolutional neural networks alleviate the demand of knowledge of process in order for model development, and lifts dependence on an engineer's personal experience on model tuning. Briefly, a deep CNN model for post-exposure processes consists of an input and an output layer, as well as multiple hidden layers, such as convolutional layers, normalization layers, and pooling layers. The parameters of the hidden layers are optimized to give a minimum value of a loss function. In embodiment, CNN models may be trained to model the behavior of any process, or a combination of processes related to the patterning process.

FIG. 3 is a flow chart for a method 300 of training a machine learning model 305 (e.g., CNN) configured to predict values of a physical characteristic associated with a substrate for use in adjusting a patterning process. The training method is a more accurate training method compared to existing methods. For example, the training is based on reducing specific errors (e.g., via a first cost function, a second cost function, a grid dependency error, an edge placement error, etc. in one or more training steps) associated with the model prediction by applying specific weight factors, for example, in CNN, where the weights are related to these errors thereby improving the overall modelling quality.

After the training, the machine learning model 305 may be referred as a trained machine learning model 305′. The training machine learning model 305′ can be further executed to determine physical characteristics. Further, a patterning process parameters (e.g., dose, focus, OPC, etc.) may be adjusted based on the physical characteristic values to improve the patterning process.

The method involves training the machine learning model 305 in continuation steps to model a process (e.g., post-exposure processes) of the patterning process. The continuation steps refer to training the machine learning model 305 using a first cost function to determine an initial set of model parameter values and using such initial model parameter values to further train the machine learning model 305 using a second cost function. Such continuous step training helps faster convergence and results in more accurate model than a one step training process involving a single cost function. The method 300 is further discussed in detail below.

Procedure P301 involves obtaining a reference image 301 associated with a desired pattern to be printed on a substrate. In an embodiment, the obtaining of the reference image 301 involves executing a process model configured to generate the reference image 301 as output, where the process model models a portion of the patterning process. In an embodiment, the process model is a calibrated model of an optics model, a resist model, and/or an etch model of the patterning process. Accordingly, in an embodiment, the reference image 301 is an aerial image, a resist image, and/or a etch image of the desired pattern.

Procedure P303 involves determining a first set of model parameter values 303 of the machine learning model 305 such that a first cost function is reduced from an initial value of the cost function obtained using an initial set of model parameter values. In an embodiment, the first cost function is a difference between the reference image 301 and an image generated via the machine learning model 305. In an embodiment, the reference image 301 and the generated image are pixelated images. Accordingly, the first cost function may be a difference in intensity values of the pixelated images. The intensity of a pixel indicates presence or absence of a feature. For example, a peak intensity signal indicates an edge of a feature (e.g., contact hole) in the image.

In an embodiment, the determining of the first set of model parameter values 303 of the machine learning model 305 is an iterative process. An iteration involves generating the image by executing the machine learning model 305 using the desired pattern; determining the difference between the generated image and the reference image 301; and adjusting model parameter values of the machine learning model 305 such that the difference is reduced. In an embodiment, the difference between the generated image and the reference image 301 is minimized.

Thus, using the first initial set of model values, the machine learning model 305″ (model 305″ refers to the machine learning model 305 having model parameter values 303) can accurate predict an aerial image, a resist image or the etch image associated with a substrate. Further, from the predicted image contours and physical characteristics of a pattern may be extracted for further analysis or improvement of the patterning process.

In an embodiment, the model parameters are weights and/or bias associated with one or more layers of the machine learning model 305. In embodiment, the machine learning model 305 is a convolution neural network including multiple layers, each associated with weights and/or bias.

Further, procedure P305 involves training, using the first set of model parameter values 303, the machine learning model 305″ such that a combination of the first cost function and a second cost function is reduced. In an embodiment, the combination of the first cost function (CF1) and the second cost function (CF2) is computed using expression c1*CF1+c2*CF2, where c1 and c2 are coefficients that can be adjusted to minimized the combination.

In an embodiment, the second cost function is a difference between measured values 304 and predicted values of the physical characteristic associated with the desired pattern, the predicted values being predicted via the machine learning model 305″. After the end of the training process, the trained machine learning model 305′ configured to determine the physical characteristics of a pattern to be imaged in the substrate is obtained.

In an embodiment, the physical characteristic determined from the predicted image is a critical dimension or an edge placement error associated with the desired pattern. In an embodiment, the physical characteristic is determined using the contours of the pattern in the predicted image of the model. For example, an algorithm may be employed to define gauge points along the contour, and cutlines that intersect the contour at gauge locations. Further, to determine a CD, distances may be measure between gauge points. Similarly, EPE may be measured using the gauge points with respect to a reference contour (e.g., associated with the reference image 301)

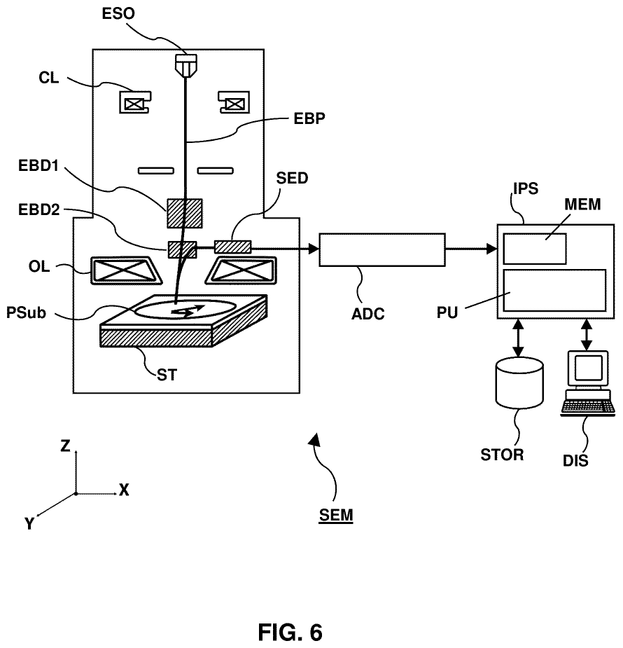

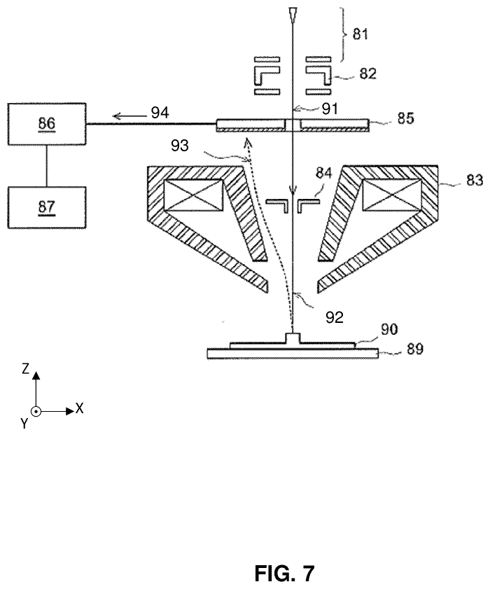

In an embodiment, the measured values 304 are for example, CD values obtained via the metrology tool configured to measure a desired printed pattern of the substrate. In an embodiment, the metrology tool is a scanning electron microscope (SEM) (e.g., see FIGS. 6-7) and the measure values are obtained from a SEM image. In an embodiment, the measured values 304 are intensity values of an aerial image associated with the desired pattern. Thus, during the training process, the measured values 304 (e.g., CD) are compared with the predicted physical characteristics (e.g., predicted CD). The training is performed such that the predicted values closely match the measured values 304.

In an embodiment, the training of the machine learning model 305 is an iterative process. An iteration involves initializing the model parameters of the machine learning model 305 with the first set of model parameter values 303; predicting the values of the physical characteristic associated with the substrate by executing the machine learning model 305″ using the desired pattern; obtaining, via a metrology tool, the measured values 304 of the physical characteristic of a desired printed pattern on the substrate; and adjusting model parameter values of the machine learning model 305″ such that a combination of the first cost function and the second cost function is reduced.

In an embodiment, the adjusting of the model parameter values is based on a gradient descent of a combination of the first and the second cost function. In an embodiment, a sum of the first cost function and the second cost function is minimized. In an embodiment, the adjusting of the model parameter values of the machine learning model 305 involves determining a gradient map of the sum of the first cost function and the second cost function as a function of a model parameter. Then, based on the gradient map, the model parameter values are determined such that the sum of the cost function are minimized.

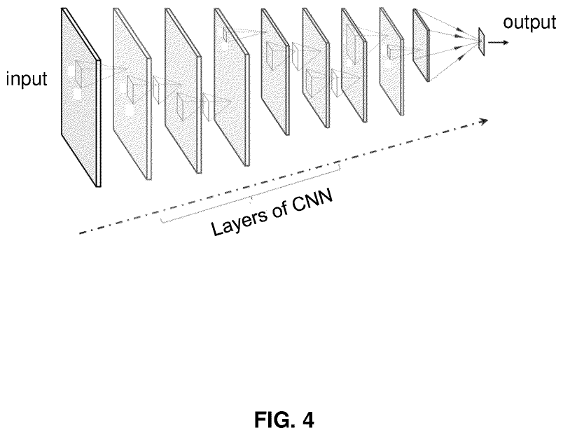

In an embodiment, the adjusting of the model parameter values comprises adjusting values of: one or more weights of a layer of the convolutional neural network, one or more bias of a layer of the convolutional neural network, hyperparameters of the CNN and/or a number of layers of the CNN. In an embodiment, the number of layers is a hyperparameter of the CNN which may be pre-selected and may not be changed during the training process. In an embodiment, a series of training process may be performed where the number of layers may be modified. An example of CNN is illustrated in FIG. 4.

In an embodiment, the training (e.g., CNN of FIG. 4) involves determining a value of the first cost function and progressively adjusting weights of one or more layers of the CNN such that the first cost function is reduced (in an embodiment, minimized). In an embodiment, the first cost function is a difference between a predicted resist image or a predicted aerial image (e.g., an output vector of CNN) and a real resist image obtained (e.g., using a SEM tool) from a printed substrate. The first cost function or the difference is reduced by modifying the values of the CNN model parameters (e.g., weights, bias, stride, etc.). In an embodiment, the first cost function is computed as CF1=ƒ(reference image−CNN(input, cnn_parameters). In this step, the input to CNN includes the measured images or the simulated images (e.g., AI/RI), and cnn_parameters has initial values that may be randomly selected. After several iterations of training, optimized cnn_parameters values are obtained and further used as the first set of model parameter values 303 for further training.

In further training, after reducing (or minimizing) the first cost function, physical characteristics may be extracted from the predicted image of the machine learning model 305. For example, CD or EPE values from the predicted resist image, or intensity values from the predicted aerial image may be extracted. These predicted CD, EPE and/or intensity values are compared with the measured values 304 to further train the machine learning model 305 using the second cost function associated with the physical characteristics in addition to the first cost function.

For example, the second cost function may be an edge placement error (EPE). In this case, measured values of EPE and the predicted EPE are used determine the second cost function. In an embodiment, the second cost function may be expressed as: CF2=ƒ(measured values−CNN(input, cnn_parameters), where the CF2 may be EPE, the function ƒ(.) performs contour extraction from the predicted pattern (e.g., by the CNN) and further determines the difference. In an embodiment, the input to this CNN includes the predicted images (e.g., AI/RI). The cnn_parameters may be weights and bias of the CNN and the cnn_parameters values are initial model parameter values obtained based on the first cost function.

In embodiment, a gradient corresponding to the cost function (e.g., the first cost function and/or the second cost function) may be dcost/dparameter, where the cnn_parameters values may be updated based on an equation (e.g., parameter=parameter−learning_rate*gradient). In an embodiment, the parameter may be the weight and/or bias, and learning_rate may be a hyperparameter used to tune the training process and may be selected by a user or a computer to improve convergence (e.g., faster convergence) of the training process.

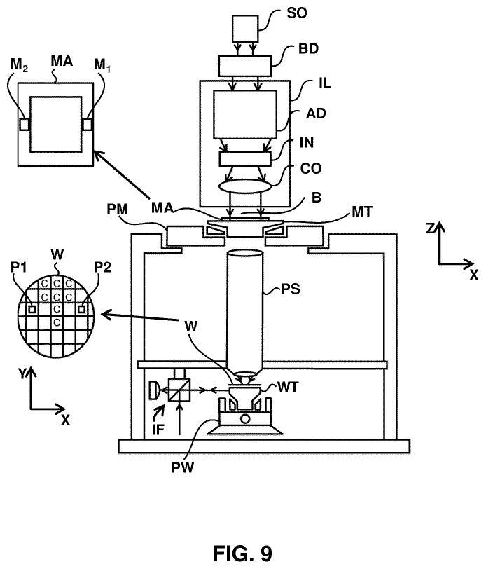

In an embodiment, the trained machine learning model 305′ (e.g., trained CNN of FIG. 9) can be further used for correcting the simulated patterns or any characteristic thereof.

In an embodiment, the method 300 may further involve procedure P305 that employs a third cost function for further training the trained machine learning model 305′. The procedure P305 involves training, using the first set of model parameter values 303, the machine learning model 305′ such that a combination of the first cost function, the second cost function, and a third cost function is reduced (in an embodiment, minimized). In an embodiment, the third cost function is a function of a grid dependency.

The grid dependency error relates to a simulation mechanism (e.g., image-based) used during simulation of a patterning process. In an embodiment, the simulation of one or more process model is image-based, where a grid may be placed on an image (e.g., an image of a substrate pattern) and during simulation only features on the grid are evaluated, while off-grid features are interpolated. Such interpolation may result in inaccurate simulation results (e.g., a substrate pattern). Further, a grid size can affect the simulation speed as well as accuracy of results. Small grid size gives accurate simulation results, but significantly slows down the simulation. Thus, larger grids may be used for faster simulation that may negatively affect the accuracy of the simulation results (e.g., simulated substrate pattern).

Typically, simulation is an iterative process, so any shift in pattern placement with respect to the grid in each iteration will induce an error in predicted patterns. As such, simulation results comprising grid dependency errors may be used to determine parameters (e.g., dose, focus, mask pattern, etc.) of the patterning process, for example, to improve the patterning process. Due to the grid-dependency error, the determined parameters may be not result a desired yield of the patterning process. Hence, grid-dependency error should be removed or minimized. According to the present disclosure, such grid dependency error is handled via the third cost function.

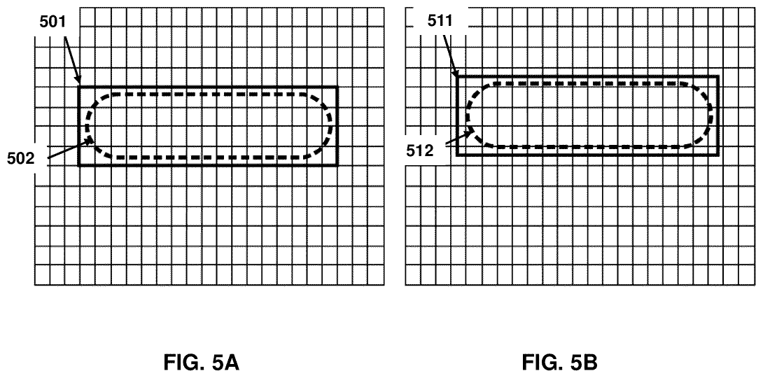

FIGS. 5A-5B illustrate example pattern shift with respect to a grid causing grid-dependency error. The Figures show, a predicted contour 501/511 (dotted) and input contour 502/512 (e.g., design or desired contour). In FIG. 5A, the entire input contour 501 is on the grid, however in FIG. 5B, a portion of the input contour 511 is off-grid e.g., at corner point. This causes a difference in model prediction contours 502 and 512. In an embodiment, e.g., LMC or OPC applications, the same pattern may be presented repeatedly at different locations on the grid, and it is desired to have an invariant model prediction, regardless of the pattern's position. However, no model can achieve a perfect shift-invariance. Some ill-conditioned model may give large contour difference between pattern shifts.

In an embodiment, the Grid Dependency (GD) error may be measured as follows. To measure the GD error, the pattern and a gauge along the contour are shifted together in a sub-pixel step. For example, for pixel size=14 nm, the pattern/gauge may be shifted by 1 nm per step along x- and/or y-direction. With each shift, a model predicted CD along the gauge is measured. Then, the variance in the set of model predicted CDs indicates the grid dependency error.

In an embodiment, the training machine learning model can be employed for various applications related to the patterning process to improve the yield of the patterning process. For example, the method 300 further involves predicting, via the trained machine learning model, substrate images for the design layout; determining, via OPC simulation using the design layout and the predicted substrate images, a mask layout to be used for manufacturing the mask for a patterning process. In an embodiment, the OPC simulation involves determining, via simulating a patterning process model using geometric shapes of the design layout and the corrections associated with the plurality of segments, a simulated pattern that will be printed on a substrate; and determining optical proximity corrections to the design layout such that a difference between the simulated pattern and the design layout is reduced. In an embodiment, the determining optical proximity corrections is an iterative process. An iteration involves adjusting the shapes and/or sizes of the geometric shapes of primary features of the design layout and/or the one or more assist features such that a performance metric of the patterning process is reduced. In an embodiment, the one or more assist features are extracted from the predicted post-OPC image of the machine learning model.

In some embodiments, the inspection apparatus may be a scanning electron microscope (SEM) that yields an image of a structure (e.g., some or all the structure of a device) exposed or transferred on the substrate. FIG. 6 depicts an embodiment of a SEM tool. A primary electron beam EBP emitted from an electron source ESO is converged by condenser lens CL and then passes through a beam deflector EBD1, an E×B deflector EBD2, and an objective lens OL to irradiate a substrate PSub on a substrate table ST at a focus.

When the substrate PSub is irradiated with electron beam EBP, secondary electrons are generated from the substrate PSub. The secondary electrons are deflected by the E×B deflector EBD2 and detected by a secondary electron detector SED. A two-dimensional electron beam image can be obtained by detecting the electrons generated from the sample in synchronization with, e.g., two dimensional scanning of the electron beam by beam deflector EBD1 or with repetitive scanning of electron beam EBP by beam deflector EBD1 in an X or Y direction, together with continuous movement of the substrate PSub by the substrate table ST in the other of the X or Y direction.

A signal detected by secondary electron detector SED is converted to a digital signal by an analog/digital (A/D) converter ADC, and the digital signal is sent to an image processing system IPU. In an embodiment, the image processing system IPU may have memory MEM to store all or part of digital images for processing by a processing unit PU. The processing unit PU (e.g., specially designed hardware or a combination of hardware and software) is configured to convert or process the digital images into datasets representative of the digital images. Further, image processing system IPU may have a storage medium STOR configured to store the digital images and corresponding datasets in a reference database. A display device DIS may be connected with the image processing system IPU, so that an operator can conduct necessary operation of the equipment with the help of a graphical user interface.

As noted above, SEM images may be processed to extract contours that describe the edges of objects, representing device structures, in the image. These contours are then quantified via metrics, such as CD. Thus, typically, the images of device structures are compared and quantified via simplistic metrics, such as an edge-to-edge distance (CD) or simple pixel differences between images. Typical contour models that detect the edges of the objects in an image in order to measure CD use image gradients. Indeed, those models rely on strong image gradients. But, in practice, the image typically is noisy and has discontinuous boundaries. Techniques, such as smoothing, adaptive thresholding, edge-detection, erosion, and dilation, may be used to process the results of the image gradient contour models to address noisy and discontinuous images, but will ultimately result in a low-resolution quantification of a high-resolution image. Thus, in most instances, mathematical manipulation of images of device structures to reduce noise and automate edge detection results in loss of resolution of the image, thereby resulting in loss of information. Consequently, the result is a low-resolution quantification that amounts to a simplistic representation of a complicated, high-resolution structure.

So, it is desirable to have a mathematical representation of the structures (e.g., circuit features, alignment mark or metrology target portions (e.g., grating features), etc.) produced or expected to be produced using a patterning process, whether, e.g., the structures are in a latent resist image, in a developed resist image or transferred to a layer on the substrate, e.g., by etching, that can preserve the resolution and yet describe the general shape of the structures. In the context of lithography or other pattering processes, the structure may be a device or a portion thereof that is being manufactured and the images may be SEM images of the structure. In some instances, the structure may be a feature of semiconductor device, e.g., integrated circuit. In this case, the structure may be referred as a pattern or a desired pattern that comprises a plurality of feature of the semiconductor device. In some instances, the structure may be an alignment mark, or a portion thereof (e.g., a grating of the alignment mark), that is used in an alignment measurement process to determine alignment of an object (e.g., a substrate) with another object (e.g., a patterning device) or a metrology target, or a portion thereof (e.g., a grating of the metrology target), that is used to measure a parameter (e.g., overlay, focus, dose, etc.) of the patterning process. In an embodiment, the metrology target is a diffractive grating used to measure, e.g., overlay.

FIG. 7 schematically illustrates a further embodiment of an inspection apparatus. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 6 that uses a probe to inspect a substrate, the electron current in the system of FIG. 7 is significantly larger compared to, e.g., a CD SEM such as depicted in FIG. 6, such that the probe spot is large enough so that the inspection speed can be fast. However, the resolution may not be as high as compared to a CD SEM because of the large probe spot. In an embodiment, the above discussed inspection apparatus may be single beam or a multi-beam apparatus without limiting the scope of the present disclosure.

The SEM images, from, e.g., the system of FIG. 6 and/or FIG. 7, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images.

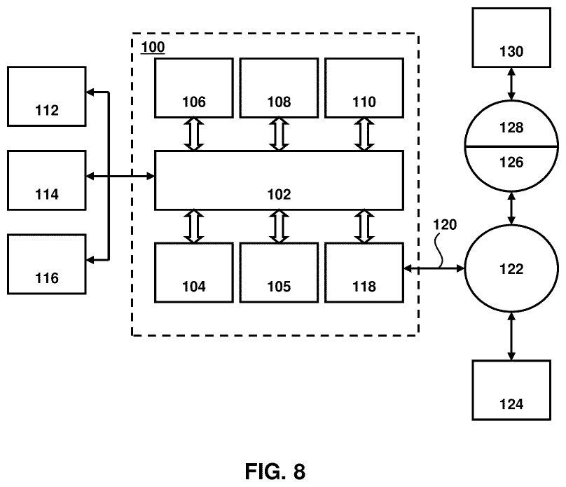

FIG. 8 is a block diagram that illustrates a computer system 100 which can assist in implementing methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also desirably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are example forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

FIG. 9 schematically depicts an exemplary lithographic projection apparatus in conjunction with the techniques described herein can be utilized. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 9 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 9. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

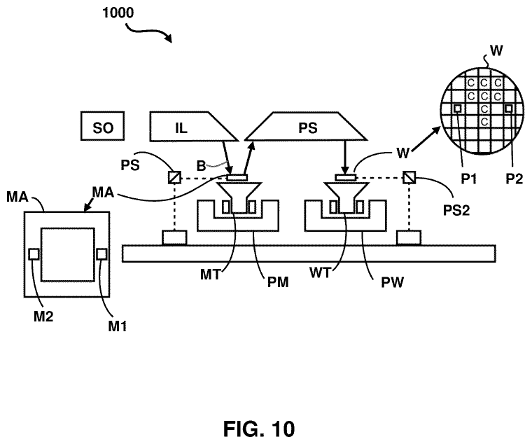

FIG. 10 schematically depicts another exemplary lithographic projection apparatus 1000 that includes:
a source collector module SO to provide radiation.
an illumination system (illuminator) IL configured to condition a radiation beam B (e.g. EUV radiation) from the source collector module SO.
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the patterning device may have multilayer reflectors comprising, for example, a multi-layer stack of molybdenum and silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 10, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 10, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the radiation source may be an integral part of the source collector module, for example when the radiation source is a discharge produced plasma EUV generator, often termed as a DPP radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.

3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

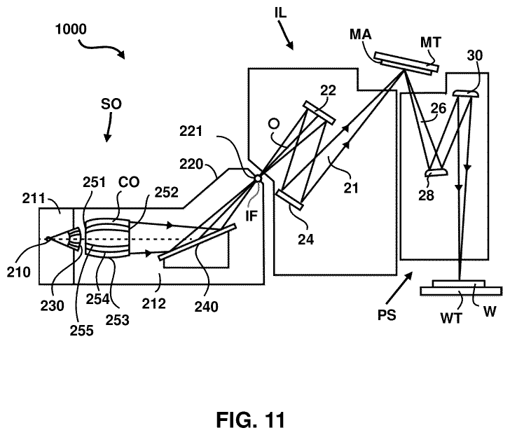

FIG. 11 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma radiation source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 11.

Collector optic CO, as illustrated in FIG. 11, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma radiation source.

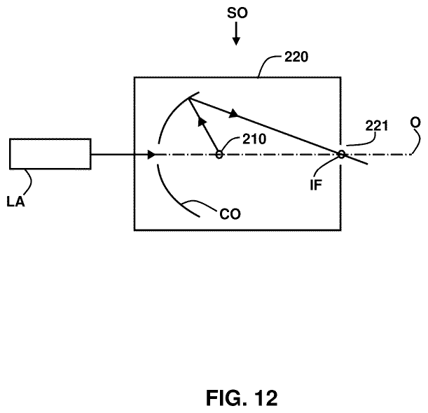

Alternatively, the source collector module SO may be part of an LPP radiation system as shown in FIG. 12. A laser LAS is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing wavelengths of an increasingly smaller size. Emerging technologies already in use include EUV (extreme ultra violet) lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Although specific reference may be made in this text to the use of embodiments in the manufacture of ICs, it should be understood that the embodiments herein may have many other possible applications. For example, it may be employed in the manufacture of integrated optical systems, guidance and detection patterns for magnetic domain memories, liquid-crystal displays (LCDs), thin film magnetic heads, micromechanical systems (MEMs), etc. The skilled artisan will appreciate that, in the context of such alternative applications, any use of the terms “reticle”, “wafer” or “die” herein may be considered as synonymous or interchangeable with the more general terms “patterning device”, “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create, for example, a multi-layer IC, so that the term substrate used herein may also refer to a substrate that already contains multiple processed layers.

In the present document, the terms “radiation” and “beam” as used herein encompass all types of electromagnetic radiation, including ultraviolet radiation (e.g. with a wavelength of about 365, about 248, about 193, about 157 or about 126 nm) and extreme ultra-violet (EUV) radiation (e.g. having a wavelength in the range of 5-20 nm), as well as particle beams, such as ion beams or electron beams.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

Embodiments of the present disclosure can be further described by the following clauses.

1. A method of training a machine learning model configured to predict values of a physical characteristic associated with a substrate for use in adjusting a patterning process, the method comprising:
obtaining a reference image associated with a desired pattern to be printed on the substrate;
determining a first set of model parameter values of the machine learning model such that a first cost function is reduced from an initial value of the cost function obtained using an initial set of model parameter values, wherein the first cost function is a difference between the reference image and an image generated via the machine learning model; and
training, using the first set of model parameter values, the machine learning model such that a combination of the first cost function and a second cost function is iteratively reduced,
   wherein the second cost function is a difference between measured values and predicted values of the physical characteristic associated with the desired pattern, the predicted values being predicted via the machine learning model.
      2. The method of clause 1, wherein the obtaining of the reference image comprises:
executing a process model configured to generate the reference image as output, wherein the process model models a portion of the patterning process.
   3. The method of clause 2, wherein the process model is a calibrated model of an optics model, a resist model, and/or an etch model of the patterning process.
   4. The method of any of clauses 1-3, wherein the reference image is an aerial image, a resist image, and/or a etch image of the desired pattern.
   5. The method of any of clauses 1-4, wherein the determining of the first set of model parameter values of the machine learning model is an iterative process, an iteration comprises:
generating the image by executing the machine learning model using the desired pattern;
determining the difference between the generated image and the reference image; and
adjusting model parameter values of the machine learning model such that the difference is reduced.
   6. The method of any of clauses 1-5, wherein the difference between the generated image and the reference image is minimized.
   7. The method of clauses 1-6, wherein the training of the machine learning model is an iterative process, an iteration comprises:
initializing the model parameters of the machine learning model with the first set of model parameter values;
predicting the values of the physical characteristic associated with the substrate by executing the machine learning model using the desired pattern;
obtaining, via a metrology tool, the measured values of the physical characteristic of a desired printed pattern on the substrate; and
adjusting model parameter values of the machine learning model such that the combination of the first cost function and the second cost function is reduced.
   8. The method of clause 7, wherein the adjusting model parameter values is based on a gradient descent of the combination of the first cost function and the second cost function.
   9. The method of any of clauses 1-8, wherein the sum of the first cost function and the second cost function is minimized.
   10. The method of any of clauses 1-9, wherein the model parameters are weights and/or bias associated with one or more layers of the machine learning model.
   11. The method of any of clauses 1-10, wherein the machine learning model is a convolution neural network.
   12. The method of any of clauses 1-11, wherein the parameter associated with a substrate is a critical dimension or an edge placement error associated with the desired pattern.
   13. The method of any of clauses 10-12, wherein the weights of the convolution neural network are adjusted to reduce the edge placement error or a model error associated with a model of the patterning process being trained.
   14. The method of any of clauses 1-13, wherein the measured values are CD values obtained via the metrology tool configured to measure a desired printed pattern of the substrate.
   15. The method of any of clauses 7-14, wherein the metrology tool is a scanning electron microscope (SEM) and the measure values are obtained from a SEM image.
   16. The method of any of clauses 1-15, wherein the measured values are intensity values of an aerial image associated with the desired pattern.
   17. The method of any of clauses 1-11, further comprising:
training, using the first set of model parameter values, the machine learning model such that a combination of the first cost function, the second cost function, and a third cost function is reduced,
   wherein the third cost function is a function of a grid dependency.
      18. The method of any of clauses 1-17, further comprising:
predicting, via the trained machine learning model, substrate images for the design layout;
determining, via OPC simulation using the design layout and the predicted substrate images, a mask layout to be used for manufacturing the mask for a patterning process.
   19. The method of clause 17, wherein the OPC simulation comprises:
determining, via simulating a patterning process model using geometric shapes of the design layout and the corrections associated with the plurality of segments, a simulated pattern that will be printed on a substrate; and
determining optical proximity corrections to the design layout such that a difference between the simulated pattern and the design layout is reduced.
   20. The method of clause 19, wherein the determining optical proximity corrections is an iterative process, an iteration comprises:
adjusting the shapes and/or sizes of the geometric shapes of primary features of the design layout and/or the one or more assist features such that a performance metric of the patterning process is reduced.
   21. The method of clause 20, wherein the one or more assist features are extracted from the predicted post-OPC image of the machine learning model.
   22. The method of any of clauses 1-21, wherein the combination of the first cost function (CF1) and the second cost function (CF2) is computed using expression c1*CF1+c2*CF2, where c1 and c2 are coefficients that can be adjusted to minimize the combination.
   23. A computer program product comprising a non-transitory computer readable medium having instructions recorded thereon, the instructions when executed by a computer implementing the method of any of the above clauses.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A method of training a machine learning model configured to predict values of a physical characteristic associated with a substrate and for use in adjusting a patterning process, the method comprising:
obtaining a reference image associated with a desired pattern to be printed on the substrate;
determining a first set of model parameter values of the machine learning model such that a first cost function is reduced from a value of the first cost function obtained by using initial model parameter values, wherein the first cost function represents a difference between the reference image and an image generated via the machine learning model; and
training, by using the set of model parameter values, the machine learning model based on combination of the first cost function and a second cost function,
wherein the second cost function represents a difference between measured values and predicted values of the physical characteristic associated with the desired pattern, wherein the predicted values are predicted via the machine learning model.

2. The method of claim 1, wherein the obtaining of the reference image comprises executing a process model that models a portion of the patterning process and configured to generate the reference image as output.

3. The method of claim 2, wherein the process model is a calibrated model of an optics model, a resist model, and/or an etch model of the patterning process.

4. The method of claim 1, wherein the reference image is an aerial image, a resist image, and/or an etch image of the desired pattern.

5. The method of claim 1, wherein the determining the set of model parameter values of the machine learning model is an iterative process, an iteration comprising:
generating the image generated via the machine learning model by executing the machine learning model using the desired pattern;
determining the difference between the generated image and the reference image; and
adjusting one or more model parameter values of the machine learning model such that the difference is reduced.

6. The method of claim 1, wherein the training of the machine learning model is an iterative process and comprises initializing model parameters of the machine learning model with the set of model parameter values, an iteration comprising:
predicting the predicted values of the physical characteristic associated with the substrate by executing the machine learning model using the desired pattern;
obtaining the measured values of the physical characteristic of a desired printed pattern on the substrate; and
adjusting one or more model parameter values of the machine learning model such that the combination of the first cost function and the second cost function is reduced.

7. The method of claim 6, wherein the adjusting one or more model parameter values is based on a gradient descent of the combination of the first cost function and the second cost function.

8. The method of claim 1, wherein the machine learning model is a convolutional neural network, and wherein model parameters include a weight and/or bias associated with one or more layers of the convolutional neural network.

9. The method of claim 1, wherein the physical characteristic associated with a substrate is a critical dimension (CD) or an edge placement error associated with the desired pattern, and wherein the measured values are CD values obtained via a metrology tool.

10. The method of claim 1, wherein the measured values are intensity values of an aerial image associated with the desired pattern.

11. The method of claim 1, further comprising training, by using the set of model parameter values, the machine learning model such that a combination of the first cost function, the second cost function, and a third cost function is reduced, wherein the third cost function is a function of a grid dependency.

12. The method of claim 1, further comprising:
predicting, via the trained machine learning model, substrate images for a design layout; and
determining, via optical proximity correction (OPC) simulation using the design layout and the predicted substrate images, a mask layout to be used for manufacturing a mask for a patterning process.

13. The method of claim 12, wherein the OPC simulation comprises:
determining a simulated pattern that will be printed on a substrate; and
determining optical proximity corrections to the design layout such that a difference between the simulated pattern and the design layout is reduced.

14. The method of claim 12, wherein the determining the mask layout comprises extracting one or more assist features from the predicted post-OPC image of the machine learning model.

15. A computer program product comprising a non-transitory computer readable medium having instructions therein, the instructions, when executed by a computer system, configured to cause the computer system to at least:
obtain a reference image associated with a desired pattern to be printed on a substrate;
determine a set of model parameter values of a machine learning model such that a first cost function is reduced from a value of the first cost function obtained by using initial model parameter values, wherein the first cost function represents a difference between the reference image and an image generated via the machine learning model and the machine learning model configured to predict values of a physical characteristic associated with a substrate and for use in adjusting a patterning process; and
train, by using the set of model parameter values, the machine learning model based on a combination of the first cost function and a second cost function,
wherein the second cost function represents a difference between measured values and predicted values of the physical characteristic associated with the desired pattern, wherein the predicted values are predicted via the machine learning model.

16. The computer program product of claim 15, wherein the instructions configured to cause the computer system to obtain the reference image are further configured to cause the computer system to execute a process model that models a portion of the patterning process and configured to generate the reference image as output.

17. The computer program product of claim 15, wherein the machine learning model is a convolutional neural network, and wherein model parameters include a weight and/or bias associated with one or more layers of the convolutional neural network.

18. The computer program product of claim 15, wherein the instructions are further configured to cause the computer system to train, by using the set of model parameter values, the machine learning model such that a combination of the first cost function, the second cost function, and a third cost function is reduced, wherein the third cost function is a function of a grid dependency.

19. The method of claim 1, wherein the combination of the first cost function (CF1) and the second cost function (CF2) is computed using an expression c1*CF1+c2*CF2, where c1 and c2 are coefficients.

20. The method of claim 8, wherein weights of the convolution neural network are adjusted to reduce edge placement error or a model error associated with a model of the patterning process being trained.
